(19) United States
(12) Patent Application Publication
(10) Pub. No.: US 2009/0068503 A1
(43) Pub. Date: Mar. 12, 2009

(54) SPUTTERING APPARATUS

(76) Inventors: Mutsuki Yamazaki, Yokohama-shi (JP); Kohei Nakayama, Kawasaki-shi (JP); Yoshihiko Nakano, Yokohama-shi (JP); Wu Mei, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/196,656

(22) Filed: Aug. 22, 2008

(30) Foreign Application Priority Data
Aug. 23, 2007 (JP) P2007-217354
Aug. 4, 2008 (JP) P2008-200842

(51) Int. Cl. C23C 14/34; H01M 8/02

(52) U.S. Cl. 429/12; 204/298.13

(57) ABSTRACT

A sputtering apparatus includes: a supporting member that accommodates a base material; a first sputtering source containing platinum and having a rectangular shape; a second sputtering source containing an element different from that contained in the first sputtering source; a first magnet that is disposed to face the supporting member, the first magnet applying a first magnetic field near a surface of the first sputtering source in a first magnetic flux density; and a second magnet that is disposed to face the supporting member, the second magnet applying a second magnetic field near a surface of the second sputtering source in a second magnetic flux density, wherein at least one of the first magnetic flux density and the second magnetic flux density is configured to be variable.

### RELATED APPLICATION(S)

The present disclosure relates to the subject matter contained in Japanese Patent Application No. 2007-217354 filed on Aug. 23, 2007 and in Japanese Patent Application No. 2008-200841 filed on Aug. 4, 2008, which are incorporated herein by reference in its entirety.

### FIELD

The present invention relates to a sputtering apparatus for causing a particulate carrier having a particle size of 1 μm or less to carry a microparticle having a particle size of 10 nm or less, the apparatus being preferable to utilize for manufacturing a catalyst used in a direct methanol fuel cell (DMFC).

### BACKGROUND

A noble metal such as platinum is used as a chemical catalyst as well as jewelry. For example, noble metal is used in an exhaust gas purifier of a vehicle, a polymer electrolyte fuel cell (PEFC). Since the polymer electrolyte fuel cell using a methanol solution as a fuel can be operated at a low temperature and has a small size and weight, the polymer electrolyte fuel cell has recently been vigorously researched in order to utilize the fuel cell as a power supply to be mounted on a small device such as a mobile device. However, a further improvement in performance has been desired to widely utilize the polymer electrolyte fuel cell. Since a fuel cell serves to convert a chemical energy generated by an electrocatalytic reaction into electrical power, a high active catalyst is indispensable to the improvement in performance.

Presently, an alloy of platinum and ruthenium (which will be hereinafter referred to as “platinum-ruthenium”) is generally used as an anode catalyst of a fuel cell. However, while the fuel cell has a theoretical voltage of the electrocatalytic reaction of 1.21 V, a voltage loss by the platinum-ruthenium catalyst is approximately 0.3 V and is comparatively large. In order to reduce the voltage loss, an anode catalyst having a high activity (a methanol oxidation activity) exceeding the platinum-ruthenium has been required. In order to improve the methanol oxidation activity, there has been considered to add another element to the platinum-ruthenium alloy.

In a conventional sputtering method or evaporating method, generally, a catalytic microparticle is carried on a carbon sheet (which will be hereinafter referred to as a “carbon paper”). In this case, the evaporation is performed over only a surface of the carbon paper. Therefore, in a case in which the catalytic microparticle having a size of several nanometers is to be carried, a necessary carrying amount for a power generation cannot be obtained. Moreover, in some cases, an alloy serving as a catalyst does not form a microparticle but be formed as a thin film depending on an evaporating condition. In those cases, there is a drawback that total surface area of the catalyst is reduced and a power generating performance is largely deteriorated.

On the other hand, there is known a technique that a catalytic metal is evaporated or sputtered on a carrier particulate to carry a catalytic microparticle. An example of such technique is disclosed in JP-A-2005-264297 (counterpart U.S. publication is: US 2007/0213212 A1).

In a case in which a carbon particle is used as a carrier in the above described method, the catalytic microparticle is sputtered or evaporated while the carbon powder is stirred. In this case, even if an observation is performed through an electron microscope, a substance other than the carbon cannot be found. The reason is that a surface condition of a carbonic microparticle which is a substance to be evaporated and an evaporated atom relate to a process for forming a metallic microparticle. More specifically, in a case in which a metal is physically evaporated in a vacuum process, a thermal or kinetic energy is utilized to cause an evaporating substrate to fly like an atom and to collide with the evaporated substance. Therefore, the evaporating atom performs a migration (a free movement over a carrier surface) and is fixed to a stable place on an energy basis, and particles then grow by setting the place to be a nucleus and are bonded to form a polycrystalline film.

In a case of a carbonic microparticle having a particle size of 1 μm or less, however, a large number of defects are present on a surface. For this reason, a distance at which the evaporated atom can perform the migration is very short and there is a low probability that a necessary nucleus for a grain growth might be formed. Accordingly, in a case in which carbon powder is evaporated while stirred, the powder is moved before the nucleus is formed so that the evaporated substance does not fly. For this reason, the evaporated substance is stuck as an atom onto the surface so that a nucleation as well as the grain growth is not caused. Although a microparticle having a particle size which is equal to or greater than 2 nm and is equal to or smaller than 10 nm is to be carried on the surface of the carbon powder in order to function as a catalyst, it is unable to expect that the function of the catalyst is exhibited because the metallic atom is stuck onto the carrier surface.

### SUMMARY

According to a first aspect of the invention, there is provided a sputtering apparatus including: a supporting member that accommodates one of a particulate base material and a sheet-type base material; a first sputtering source that is disposed to face the supporting member at a first distance, the first sputtering source containing platinum and having a rectangular shape; a second sputtering source that is disposed to face the supporting member at a second distance and to be adjacent to the first sputtering source, the second sputtering source containing an element different from that contained in the first sputtering source; a first magnet that is disposed to face the supporting member at an opposite side with respect to the first sputtering source, the first magnet applying a first magnetic field near a surface of the first sputtering source in a first magnetic flux density; and a second magnet that is disposed to face the supporting member at an opposite side with respect to the second sputtering source, the second magnet applying a second magnetic field near a surface of the second sputtering source in a second magnetic flux density, wherein at least one of the first magnetic flux density and the second magnetic flux density is configured to be variable.

According to a second aspect of the invention, there is provided a sputtering apparatus including: a supporting member that accommodates one of a particulate base material and a sheet-type base material; a first sputtering source that includes at least two first sputtering source pieces that are disposed to face the supporting member, each of the first sputtering source pieces containing platinum and having a rectangular shape; a second sputtering source that is disposed to face the supporting member and to be adjacent to the first sputtering source pieces, the second sputtering source containing an element different from that contained in the first sputtering source; a magnet that is disposed to face the supporting member at an opposite side with respect to the first sputtering source and the second sputtering source, the magnet applying a magnetic field near a surface of the first sputtering source and the second sputtering source, wherein the second sputtering source is disposed between the first sputtering source pieces so as that longitudinal edges of the first sputtering source pieces and the second sputtering source are arranged to be substantially in parallel with one another, wherein the magnetic field is configured to be in a longitudinal shape that extends in a direction that is substantially orthogonal to the longitudinal edges of the first sputtering source pieces and the second sputtering source, and wherein the magnetic field is configured to be movable in a direction along the longitudinal edges of the first sputtering source pieces and the second sputtering source, by relatively moving the magnet and a set of the first sputtering source and the second sputtering source.

### BRIEF DESCRIPTION OF THE DRAWINGS

In the accompanying drawings:

FIG. 1 is a schematic plan view showing an example of an arrangement of a sputtering source and a magnetic field in an apparatus utilizing the present invention;

FIG. 2 is a schematic sectional view showing an example of the sputtering source and a magnet corresponding thereto in the apparatus;

FIG. 3 is a schematic plan view showing an example of the magnet in the apparatus;

FIG. 4 is a schematic plan view showing an example of the arrangement of the sputtering source and the magnetic field in the apparatus;

FIG. 5 is a schematic plan view showing an example of the arrangement of the sputtering source and the magnetic field in the apparatus;

FIG. 6 is a schematic plan view showing an example of the arrangement of the sputtering source and the magnetic field in the apparatus;

FIG. 7 is a schematic plan view showing an example of the arrangement of the sputtering source and the magnetic field in the apparatus;

FIG. 8 is a schematic plan view showing an example of the arrangement of the sputtering source and the magnetic field in the apparatus;

FIG. 9 is a schematic plan view showing an example of the arrangement of the sputtering source and the magnetic field in the apparatus;

FIG. 10 is a schematic plan view showing an example of the arrangement of the sputtering source and the magnetic field in the apparatus;

FIG. 11 is a schematic plan view showing an example of the arrangement of the sputtering source and the magnetic field in the apparatus;

FIG. 12 is a schematic sectional view showing an example of the sputtering source and the magnet corresponding thereto in the apparatus;

FIG. 13 is a schematic plan view showing an example of the arrangement of the sputtering source and the magnetic field in the apparatus;

FIG. 14 is a schematic plan view showing an example of the arrangement of the sputtering source and the magnetic field in the apparatus;

FIG. 15 is a schematic plan view showing an example of the arrangement of the sputtering source and the magnetic field in the apparatus;

FIG. 16 is a schematic plan view showing an example of the arrangement of the sputtering source and the magnetic field in the apparatus;

FIG. 17 is a schematic plan view showing an example of the arrangement of the sputtering source and the magnetic field in the apparatus;

FIG. 18 is a schematic sectional view showing an example of the apparatus;

FIG. 19 is a schematic sectional view showing a film and electrode complex according to an example of the present invention;

FIG. 20 is a schematic sectional view showing a single cell of a direct methanol fuel cell according to the example of the present invention;

FIGS. 21A-21C show an example configuration of the sputtering apparatus, wherein FIG. 21A is a plan view, FIG. 21B is a sectional view taken along XXIb-XXIb line shown in FIG. 21A, and FIG. 21C is a sectional view taken along XXIc-XXIc line shown in FIG. 21A;

FIG. 22 shows another example configuration of the sputtering apparatus;

FIG. 23 shows another example configuration of the sputtering apparatus;

FIG. 24 shows another example configuration of the sputtering apparatus;

FIG. 25 shows another example configuration of the sputtering apparatus;

FIG. 26 is a schematic sectional view of another example configuration of the sputtering apparatus for explaining a distance between a sputtering source and a particulate base material;

FIG. 27 is a graph showing a relationship between the distance and a deposition speed;

FIG. 28 is a schematic drawing of a direct methanol fuel cell; and

FIG. 29 is a schematic sectional view of a cell provided in the direct methanol fuel cell.

### DETAILED DESCRIPTION OF THE EMBODIMENTS

An embodiment according to the invention will be described below with reference to the accompanying drawings.

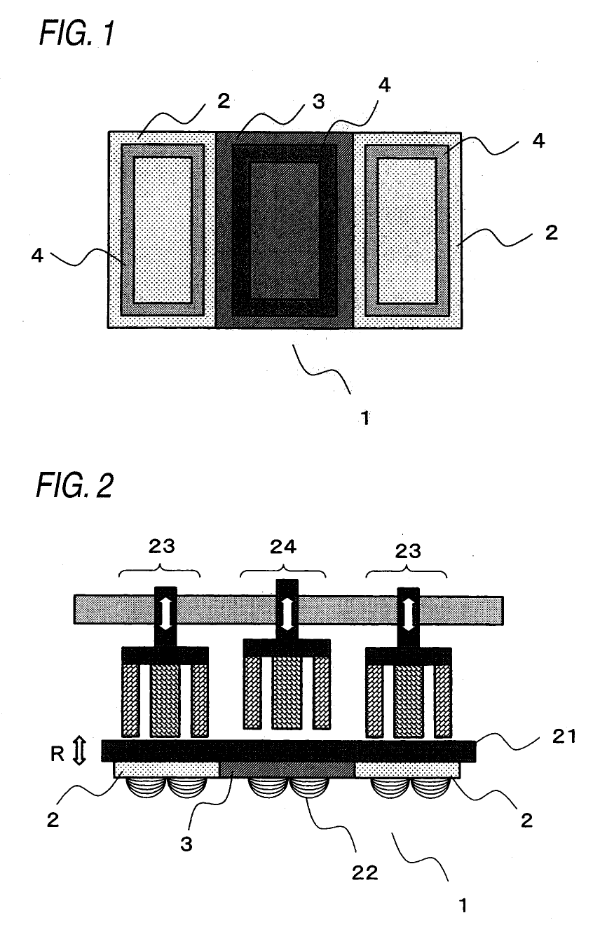

FIG. 1 shows an example of a typical plan view illustrating a sputtering source 1 used in a sputtering apparatus according to an embodiment of the present invention.

A sputtering source 1 includes a pair of first sputtering sources 2 having rectangular shapes and a second sputtering source 3 having a rectangular shape. The first sputtering sources 2 that contain platinum are disposed on both sides of the second sputtering source 3, and the second sputtering source 3 that contains other alloy elements is disposed at a center to be adjacent to each of the first sputtering sources 2. A magnetic field 4 for trapping plasma to form an erosion area on the sputtering source 1 is formed in the vicinity of surfaces of the first sputtering sources 2 and the second sputtering source 3. Magnetic flux densities of the magnetic fields 4 in the vicinity of the surfaces of the first sputtering sources 2 and the second sputtering source 3 are different from each other.

The number of the first sputtering sources 2 may not be limited to two, but the sputtering source 1 may be provided with one or more of the first sputtering sources 2. Accordingly, in the following description, the first sputtering sources 2 may be described in a singular form.

FIG. 2 shows an example of a typical plan view illustrating a sputtering source and a magnet corresponding thereto which are used in the sputtering apparatus, and lines of magnetic force. The first sputtering source 2 and the second sputtering source 3 are fixed to a backing plate 21 provided on a back by using a conductive bonding material such as In or a fixing jig (not shown) as shown in FIG. 2. Furthermore, a first magnet 23 and a second magnet 24 corresponding to the first and second sputtering sources 2 and 3 are disposed under the backing plate 21.

The magnetic flux densities of the magnetic fields 4 of the first sputtering source 2 and the second sputtering source 3 are regulated by causing the first magnet 23 and the second magnet 24 to be movable. For example, in a case in which a sputtering speed of the second sputtering source 3 is higher than that of the first sputtering source 2, the first magnet 23 corresponding to the first sputtering source 2 is made distant and the second magnet 24 corresponding to the second sputtering source 3 is made close. By the mechanism, a composition of a deposited substance can easily be regulated and an optimum composition can be obtained even if a material of each of the sputtering sources is changed.

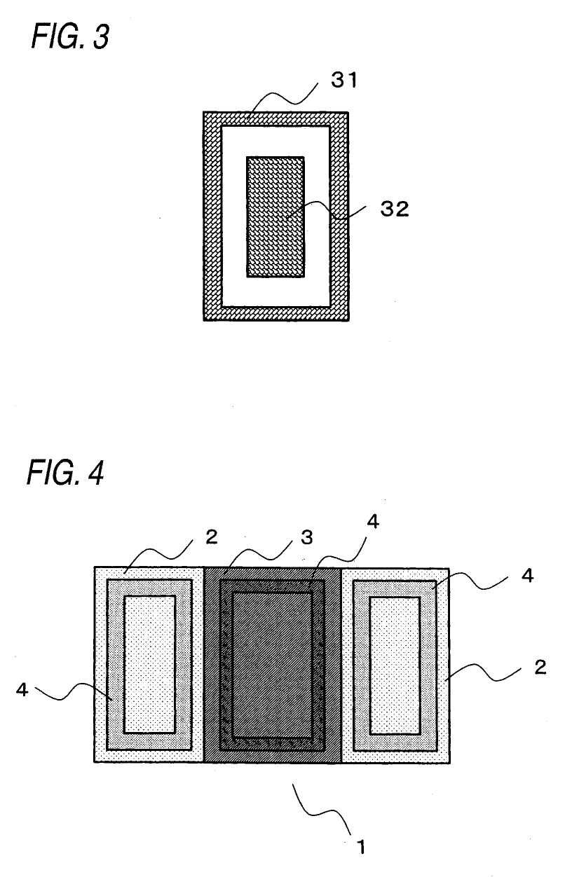

FIG. 3 shows an example of a typical sectional view showing a magnet to be used in the sputtering apparatus. As seen from sections, each of the first magnet 23 and the second magnet 24 in FIG. 2 includes a magnet 31 surrounding an outer periphery and a central magnet 32 having a different polarity. When the first magnet 23 and the second magnet 24 are caused to approach the first sputtering source 2 and the second sputtering source 3, a line of magnetic force 22 is generated in the vicinity of the surfaces of the first sputtering source 2 and the second sputtering source 3 as shown in FIG. 2. Consequently, a plasma trapping density is increased. Therefore, the magnetic field indicated as 4 in FIG. 1 is formed. Although a sputtering speed is varied depending on a material, it depends on the magnetic flux density and is changed corresponding to a sectional area, a magnetic force and a distance R from the sputtering source in each of the first magnet 23 and the second magnet 24.

There are several variations in the arrangement of the first sputtering source 2 and the second sputtering source 3 and how the magnetic field is formed, as shown in FIGS. 4 to 10.

In contrast with the configuration shown in FIG. 1, in the configuration shown in FIG. 4, a relationship between the magnetic flux densities of the magnetic fields 4 in the first sputtering source 2 and the second sputtering source 3 is reversed and the distance R between the first sputtering source 2 and the first magnet 23 corresponding thereto is increased, and the distance R between the second sputtering source 3 and the second magnet 24 corresponding thereto is reduced to enlarge the magnetic field, thereby increasing utilization efficiency of a material.

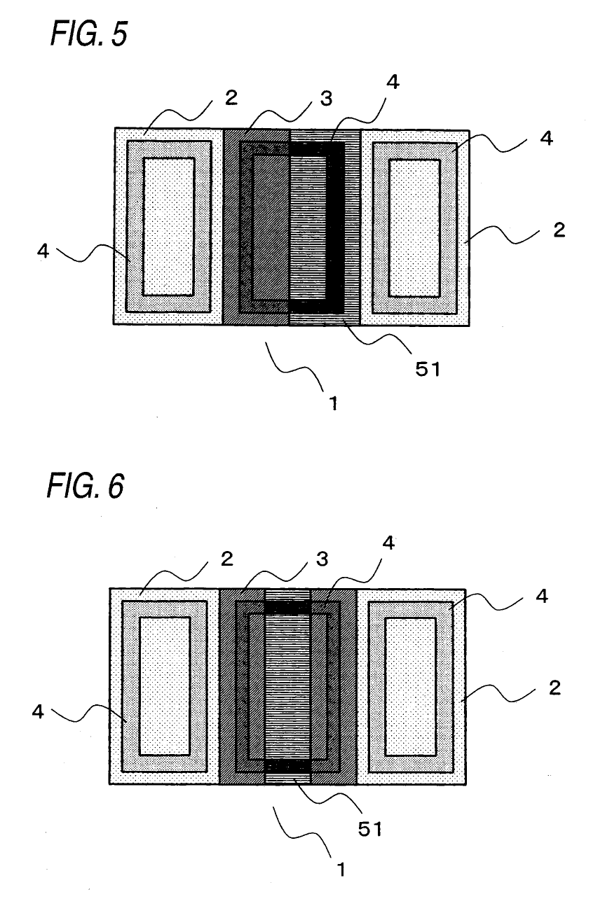

In FIG. 5, moreover, a third sputtering source 51 containing ruthenium is disposed between the first sputtering source 2 and the second sputtering source 3 in such a manner that longitudinal directions of the third sputtering source 51 and the second sputtering source 3 are parallel with each other. The magnetic flux density of the magnetic field 4 regulates the distances R between the first sputtering source 2 and second sputtering source 3 and the first magnet 23 and second magnet 24 corresponding thereto in such a manner that a deposited substance can obtain a proper composition. The first sputtering source 2, the second sputtering source 3 and the third sputtering source 51 are not alloyed but formed by a single element. Therefore, a reprocessing cost is reduced when each of the sputtering sources is used as a material again. A magnet corresponding to the third sputtering source 51 is not particularly provided.

As shown in FIG. 6, moreover, the third sputtering source 51 can be disposed on a center of the second sputtering source 3 in such a manner that longitudinal directions are substantially in parallel with each other. In this case, it is possible to further lessen a variation in the composition of the deposited substance.

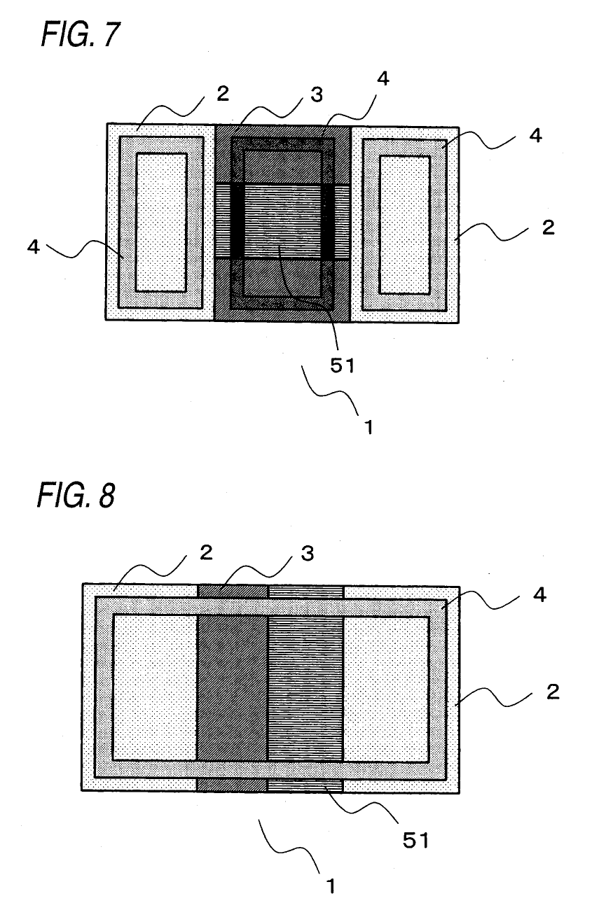

In addition, as shown in FIG. 7, it is also possible to dispose the third sputtering source 51 on the center of the second sputtering source 3 in such a manner that longitudinal directions are almost orthogonal to each other, and furthermore, to dispose the third sputtering source 51 in contact with the first sputtering source 2.

In a case in which the small-sized sputtering source 1 is used, the continuous magnetic field 4 may be formed across the first sputtering source 2, the second sputtering source 3 and the third sputtering source 51 over the whole sputtering source as shown in FIG. 8. In this case, there is prepared a magnet having a size corresponding to the whole sputtering source 1.

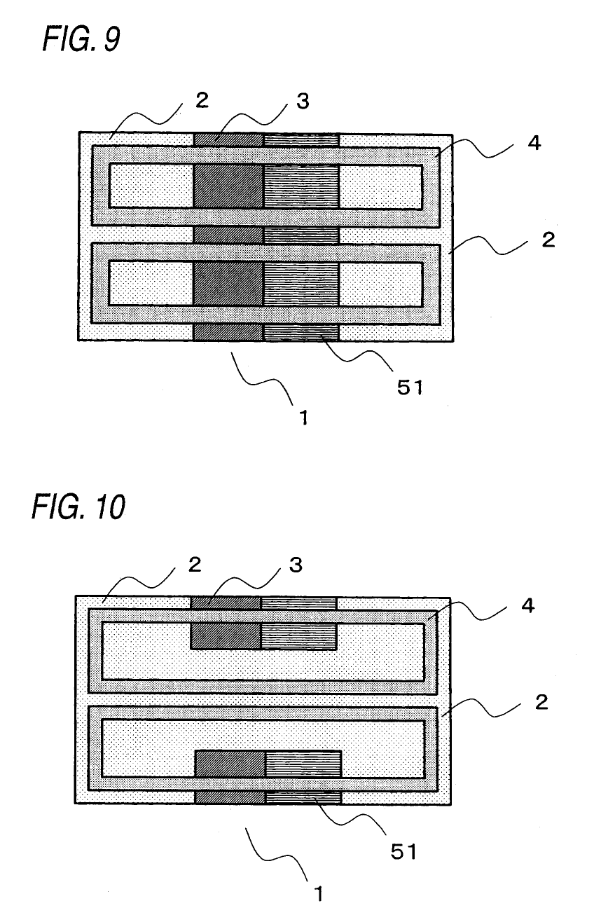

To the contrary, in a case in which the sputtering source 1 is slightly large, a plurality of magnetic fields 4 in FIG. 8 may be formed as shown in FIG. 9. Consequently, it is possible to increase the sputtering speed and to enhance the utilization efficiency of the material.

In addition, in a case in which a catalyst having a high composition ratio of the first sputtering source 2 is obtained, the magnetic fields 4 may be provided and a part of the continuous magnetic field 4 may be formed on the second sputtering source 3 and the third sputtering source 51 as shown in FIG. 10.

In a magnetron sputtering method, a material is exchanged for a new one immediately before a hole is formed in the erosion area of a sputtering source (a range in which a component element is caused to burst so that the sputtering source is consumed by a sputtering phenomenon) and a residual material is subjected to a regenerating treatment in some cases. A sputtering speed of the erosion area is usually higher than that of surroundings by two digits or more. For this reason, a rate of the material which can be used for sputtering to extremely eliminate that region is approximately 10% to 20%. Accordingly, the regenerating treatment is to be often performed. Therefore, there is increased an influence of a cost on a product.

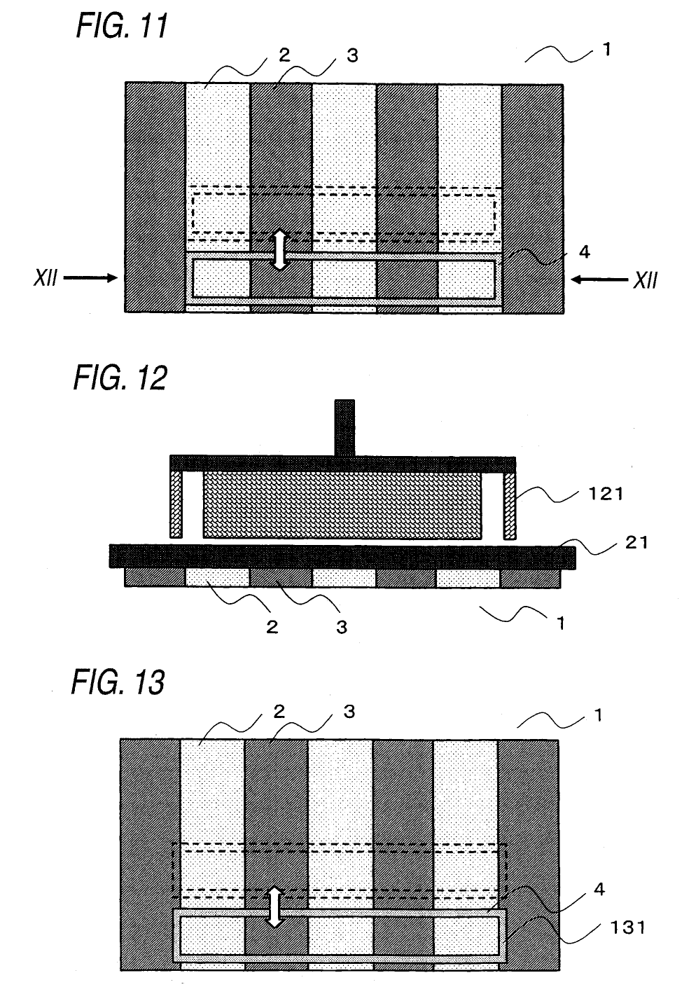

FIG. 11 shows an example of a typical plan view showing a sputtering source and a magnetic field which are used in the sputtering apparatus.

In the embodiment, the sputtering source 1 is formed, as a sputtering source intended for a mass production, by the first sputtering source 2 containing platinum and the second sputtering source 3 which are provided alternately with longitudinal directions set to be parallel with each other and the magnetic field is formed like a band or a rectangle so as to be almost orthogonal to the longitudinal directions as shown in FIG. 11, and the whole sputtering source 1 and the magnet corresponding thereto (not shown) are relatively moved in the longitudinal direction of the first sputtering source 2 or the second sputtering source 3 to sequentially perform sputtering with a scan in order to enhance the utilization efficiency of the sputtering source.

By utilizing the sputtering source 1 as configured above, even if a power to be supplied in the sputtering is set to be equal, it is possible to control the composition of the deposited substance without using an alloy sputtering source while properly regulating the magnetic flux density depending on a sputtering speed or bonding energy of a material. The residual material of the sputtering source 1 which is scraped locally and cannot be used is dissolved and reprocessed. If neither the first sputtering source 2 nor the second sputtering source 3 mixes other elements, however, the reprocessing can easily be carried out and a regenerating cost can be reduced so that the sputtering can be efficiently performed, which is preferable.

FIG. 12 is a sectional view taken along an XII-XII line shown in FIG. 11, illustrating an example of a positional relationship between the sputtering source and the magnet corresponding thereto.

As shown in FIG. 12, by previously adjusting a position of a magnet 121 with respect to the first sputtering source 2 and the second sputtering source 3, it is also possible to perform the sputtering while performing a scan. In case of FIG. 12, a scanning direction is defined as a perpendicular direction with respect to the sheet on which the FIG. 12 is shown.

FIGS. 13 to 17 show a variant of the sputtering source in a case in which the sputtering is performed while the whole sputtering source 1 and the magnet corresponding thereto are relatively moved to sequentially perform the scan.

FIG. 13 is substantially the same as FIG. 11, and the magnetic field 4 is formed like a band or a rectangle in the vicinity of the surface in the whole sputtering source 1 and an end 131 is always set to be positioned on the second sputtering source 3. Since the end 131 has a high sputtering speed, the material is required to be properly exchanged.

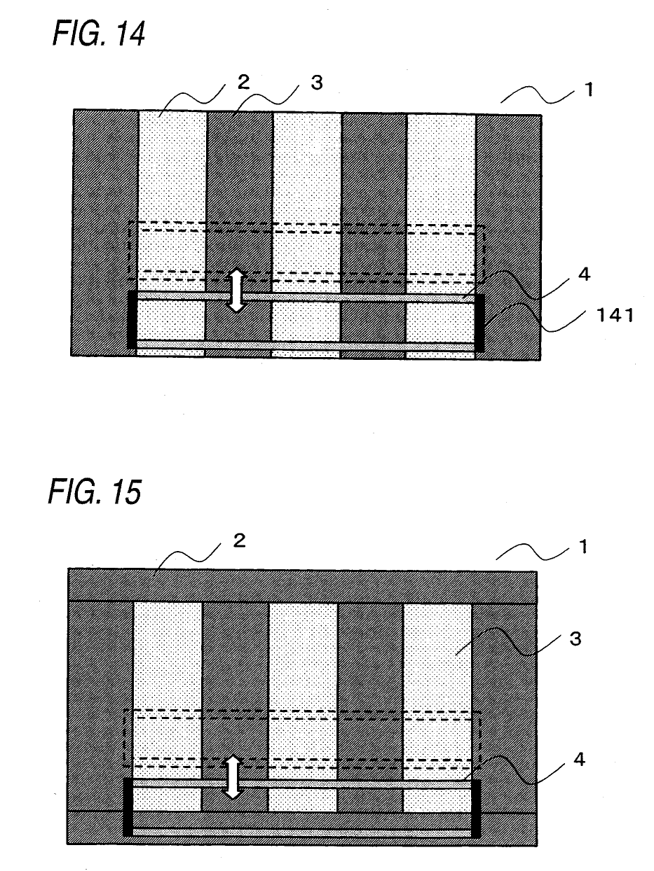

FIG. 14 is substantially the same as FIG. 13, and an end 141 of the magnetic field 4 is formed to have a slightly low magnetic flux density. The magnetic flux density of the end may reduce the magnetic force of the magnet, a distance from a backing plate may be increased or the magnet may be removed. A regulation is performed by any of the methods. By the scan, a specific material does not need to be often exchanged. Consequently, productivity can be enhanced.

FIG. 15 is a view showing an arrangement in which the first sputtering source 2 is disposed on both ends in the longitudinal direction of the first sputtering source 2 and the second sputtering source 3. A period of time for which the scanned magnetic field 4 stays in the same place is reduced as greatly as possible. Consequently, it is possible to further enhance utilization efficiency of a noble metal material while maintaining a uniformity of a composition of a deposited substance.

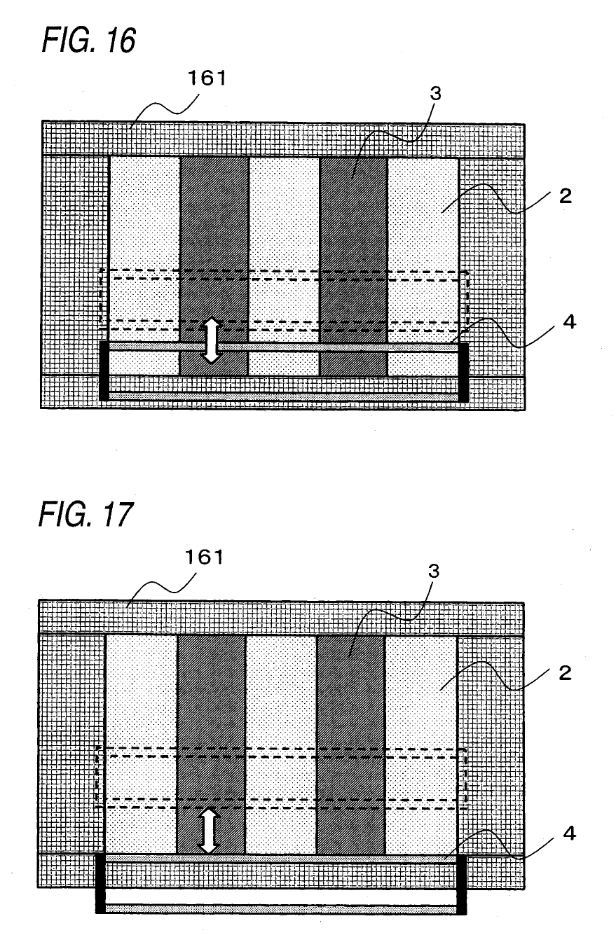

In FIG. 16, the first sputtering source 2 and the second sputtering source 3 are disposed in such a manner that the longitudinal directions are substantially in parallel with each other and an outer periphery thereof is surrounded by a material 161 having a sputtering speed which is lower than that of the first sputtering source 2 by one digit or more. For example, the material 161 includes silicon oxide, titanium oxide, zirconium oxide, tungsten oxide and molybdenum oxide. Metallic elements constituting them have the effect of enhancing an activity of a catalyst, and a very small amount of metal oxide has no bad influence. Alternatively, the material may be constituted by a polymer compound. In particular, Teflon (registered trademark: produced by DuPont Co., Ltd.) has a high degree of crystallization and has a small monomer dissociation, which is suitable.

In this case, when the magnetic field is moved to the region where the member 161 is disposed having the low sputtering speed as shown in FIG. 17, a thickness of the whole sputtering source 1 is uniformly decreased, which is desirable. In some cases, parts of the first sputtering source 2 and the second sputtering source 3 once vaporize and are then stuck to the member 161 having the low sputtering speed on the periphery. However, it is also possible to perform the sputtering over them again. Thus, it is possible to enhance the utilization efficiency of the noble metal material more greatly.

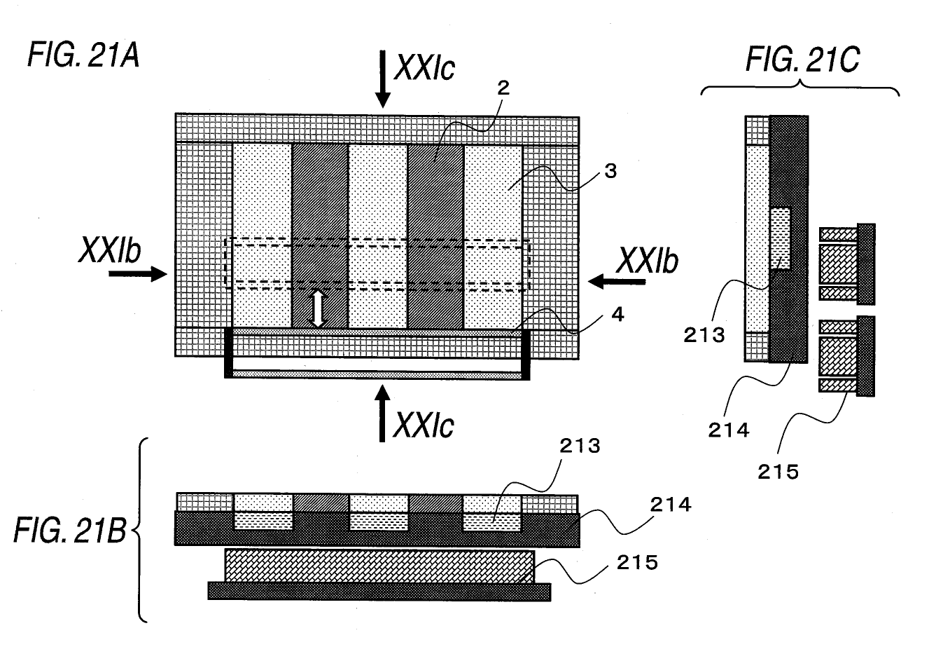

FIGS. 21A-21C show an example of a configuration for improving a usage efficiency of the first and second sputtering sources 2 and 3. As shown in FIGS. 21A-21C, a high-permeability member 213 may be disposed between the second sputtering source 3 and a supporting member (backing plate 214) that supports the first and second sputtering sources 2 and 3. The high-permeability member 213 may be formed of a material having high-permeability such as Ni, Fe, and Co, that is higher than that of sputtering source 1 (the first and second sputtering sources 2 and 3). The high-permeability member 213 may be supported by being embedded in the backing plate 214. By appropriately configuring a thickness of the high-permeability member 213, a magnetic field intensity applied to the first and second sputtering sources 2 and 3 can be adjusted, to thereby adjust the sputtering speed of the first and second sputtering sources 2 and 3 to a desired sputtering speed.

In order to improve productivity of the particle carrier, the sputtering apparatus may be configured to have a plurality of erosion areas. In a case where the sputtering apparatus is configured that the first and second sputtering sources 2 and 3 are scanned by two magnets 215 for obtaining multiple erosion areas, scanning directions of the magnets 215 need to be reversed at a center position of the first and second sputtering sources 2 and 3 in the longitudinal direction. When reversing the scanning directions of the magnets 215, the magnets 215 are stopped at the center position. Accordingly, a sputtering time of the first and second sputtering sources 2 and 3 becomes longer at the center position, causing the first and second sputtering sources 2 and 3 to be more worn than at the center position than at other areas. This may cause the first and second sputtering sources 2 and 3 to be staved, and a hole might be formed on the first and second sputtering sources 2 and 3.

In order to prevent the deterioration of the first and second sputtering sources 2 and 3, the high-permeability member 213 may be disposed at the center position to extend in a direction that is orthogonal to the longitudinal direction of the first and second sputtering sources 2 and 3. According to this configuration, the sputtering speed of the first and second sputtering sources 2 and 3 at the center position can be set to be in a range from 80% to 95% of the sputtering speed at other areas, and the wear of the first and the second sputtering sources 2 and 3 can be made to be uniform, to thereby improve the usage efficiency of the first and second sputtering sources 2 and 3.

In a case where the sputtering speed at the center position is set to be lower than 80%, the difference in the sputtering speed at the center position where the high-permeability member 213 is provided and at other areas where the high-permeability member 213 is not provided becomes large, causing a clear boundary between the center position and other areas, which is not preferable. In a case where the sputtering speed at the center position is set to be higher than 95%, the magnets 215 are required to reverse the scanning direction more quick, which requires a movement mechanism for the magnets to have more accuracy and power, causing the sputtering apparatus to have higher cost, which is not preferable.

It is more preferable to configure the sputtering apparatus so that the sputtering speed smoothly changes at the center position with in the preferable range of from 80% to 95%. For this purpose, the high-permeability member 213 may be disposed so that a reduction rate of the sputtering speed is set to become gradually small at areas away form the center position. Specifically, the thickness of the high-permeability member 213 may be formed to be thinner at a peripheral portion thereof than at a center portion. According to this configuration, the first and second sputtering sources 2 and 3 can be used more uniformly.

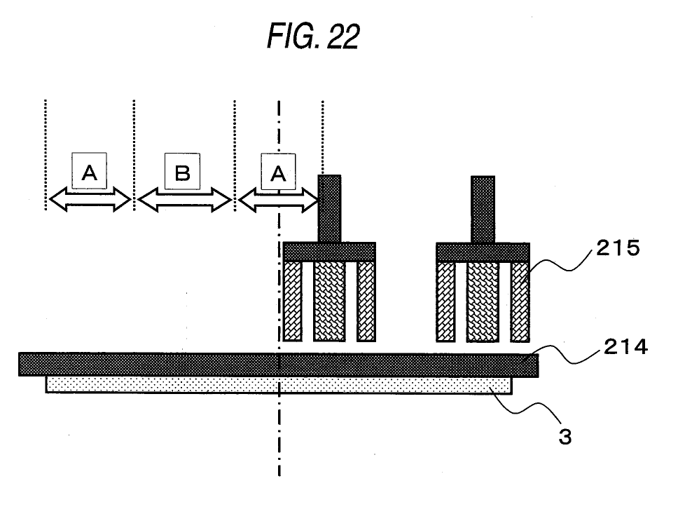

As shown in FIG. 22, the sputtering apparatus may be configured that the scanning speed of the magnets 215 is set to be 5% to 10% faster at an area A, where the scanning direction of the magnets is reversed with respect to the scanning speed at an area B other than the area A. In a case where the scanning speed at the area A is less faster than 5%, the magnets 215 are required to reverse the scanning direction more quick, which requires a movement mechanism for the magnets to have more accuracy and power, causing the sputtering apparatus to have higher cost, which is not preferable. In a case where the scanning speed at the area A is faster than 10%, a clear boundary is caused in the sputtering, which is not preferable

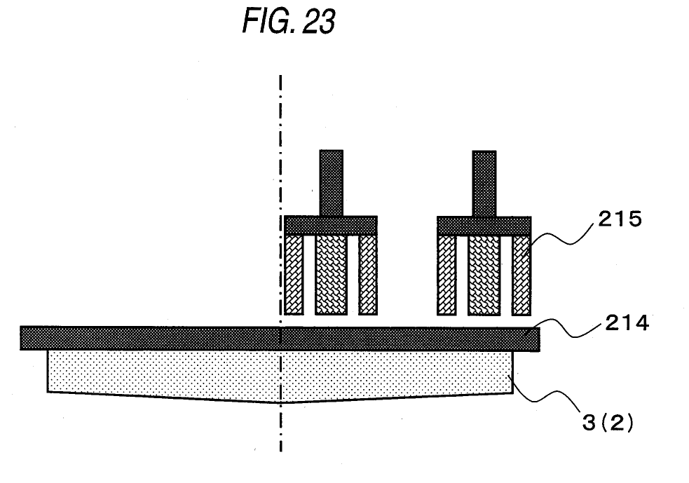

The sputtering apparatus may be configured that, as shown in FIG. 23, the thickness of the first and second sputtering sources 2 and 3 at the center position is set to be thicker than other areas. The thickness of the first and second sputtering sources 2 and 3 at the center position may be set in accordance with the sputtering speed and the length of time period for which the magnets 215 stop for reversing the scanning direction. The thickness of the first and second sputtering sources 2 and 3 at the center position may preferably be set to be 1.1 times to 1.3 times thicker than other areas.

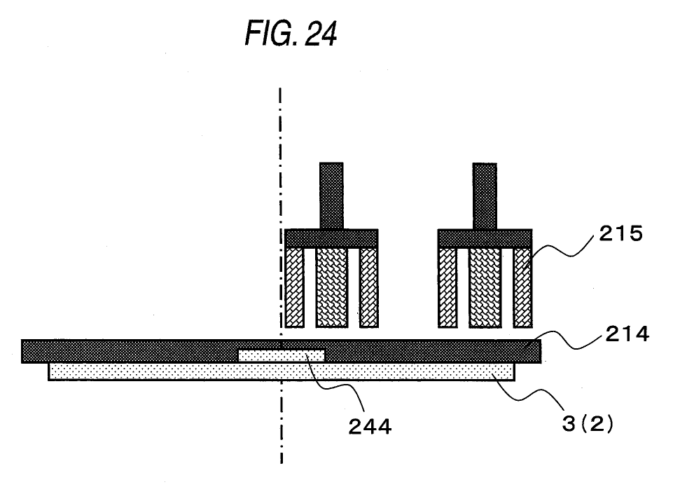

The sputtering apparatus may be configured that, as shown in FIG. 24, an additional member 244 having a plate shape and formed of a material same with those of the first and second sputtering sources 2 and 3, such as SiO₂, TiO₂, WO₃, and Mn, is disposed at the center position. By thus disposing the additional member 244, the sputtering apparatus can continue the sputtering process even the first and second sputtering sources 2 and 3 are partially staved at the center position and a hole is formed thereon.

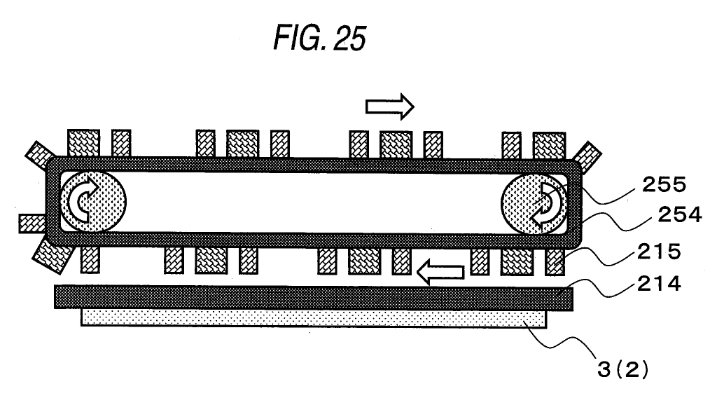

The sputtering apparatus may be configured that, as shown in FIG. 25, the magnets 215 are disposed on a belt 254 that is conveyed by a pair of rollers 255. In this configuration, the magnets 215 are conveyed by the belt 254 and scan the first and second sputtering sources 2 and 3 without reversing the scanning direction. According to this configuration, the wear of the first and second sputtering sources 2 and 3 can be uniformed, and the sputtering apparatus can continue the sputtering process for a longer time.

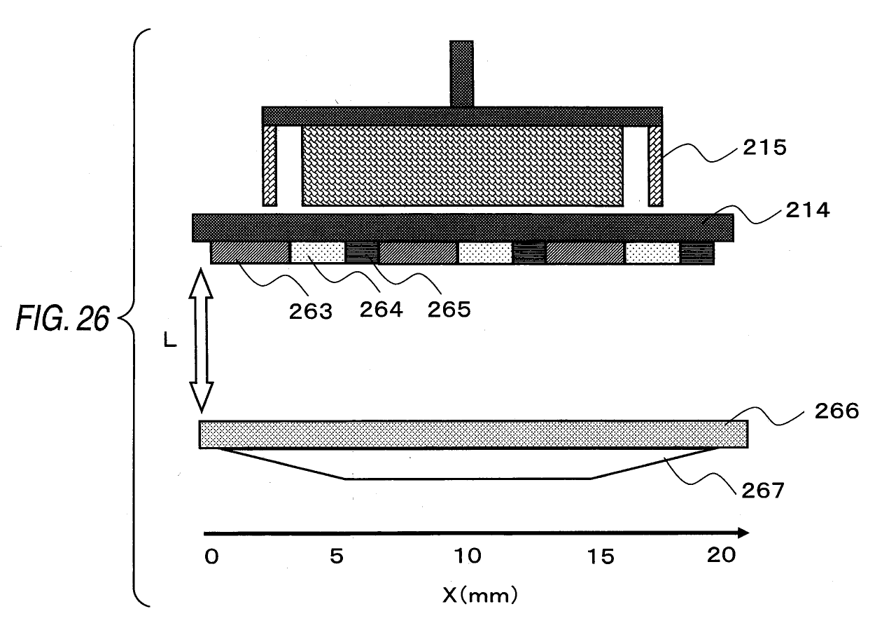

The sputtering apparatus may be configured as shown in FIG. 26. In the configuration shown in FIG. 26, a plurality of sputtering sources 263-265, which are made of different materials, are alternately arranged in a given order on the backing plate 214 and a distance L between the sputtering sources 263-265 and a carbon-based particulate base material 266 that is supported by a supporting member 267 is adjustable. By changing the distance L, a concentration distribution of the microparticulate in the particulate base material 266 can be changed.

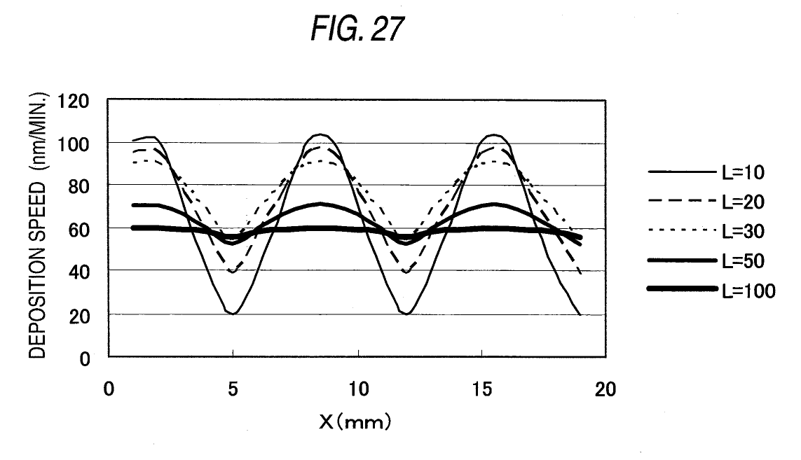

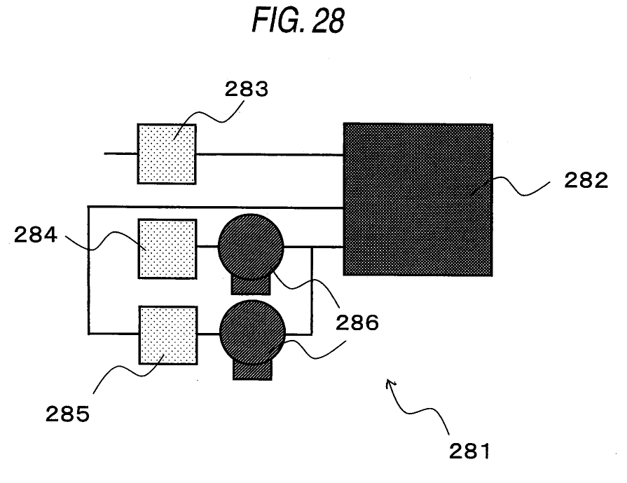

FIG. 27 shows an example of a relationship between a sputtering position and a deposition speed obtained in a case where three sputtering sources 263-265 is used, which are formed of different materials and alternately arranged in a given order. In the example, the first sputtering source 263 is Pt, the second sputtering source 264 is Ru, and the third sputtering source is WMo. As can be seen from FIG. 27, when the distance L is set to 10 mm, the sputtering speed at a position beneath the second sputtering source 264 is lowered to 20˜40 nm/min while the sputtering speed at a position beneath the first sputtering source 263 is 100 nm/min. As shown in FIG. 27, it is confirmed that the difference in the deposition speed at each positions becomes smaller as the distance L is set larger.

There may be a case where it is preferable to have a concentration distribution of a microparticulate in the particulate base material or in a sheet-type base material.

FIG. 28 shows an example of a direct methanol fuel cell (DMFC) having a configuration called an active type. As shown in FIG. 28, in the DMFC 281 includes: a cell 282; an air pump 283 that supplies air to the cell 282; a fuel tank 284; a water tank 285; and pumps 286 that supply fuel (methanol) and water from the fuel tank 284 and the water tank 285 with appropriate mixture ratio to the cell 282 to generate electric power.

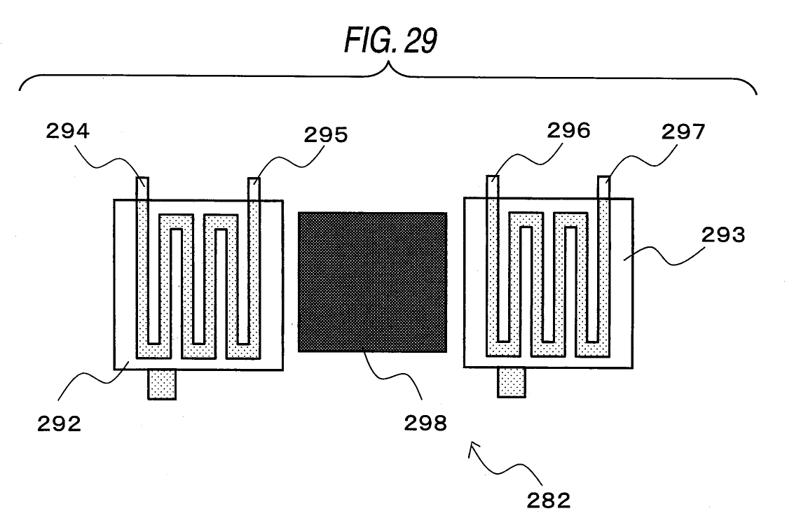

FIG. 29 is a sectional view of the cell 282. The cell 282 is provided with an anode 292 having a flow path in which a mixed fuel flows and a cathode 293 having a flow path in which air flows. The cell 282 has a membrane electrode assembly (MEA) 298 disposed between the anode 292 and the cathode 293. When generating electrical power by the DMFC 281, the methanol is consumed as a fuel. Therefore, concentration of the methanol is high at a position near a fuel inlet 294 and becomes low as the fuel flows toward a fuel outlet 295. The water flows in the cathode 293 is supplied from a water inlet 296 and output from a water outlet 297 to the water tank 285 to be recycled.

In the DMFC 281, the amount of catalytic agent should be appropriately designed to suit the concentration of the methanol in order to improve the power generation efficiency and elongate the operation life. Accordingly, the MEA 298 is configured to have more amount of catalytic agent at position near the fuel inlet 294 and lower amount of catalytic agent at position near the fuel outlet 295.

An electrode employing the MEA 298 may be assumed to be produced by changing a thickness of a catalytic agent layer by utilizing a conventional wet process. However, utilization of such method is not preferable because the thickness of the catalytic agent layer affects a diffusion characteristic of a fuel and the overall characteristic of the fuel cell may be deteriorated.

Contrary to the conventional method, by using the sputtering apparatus according to the embodiment as previously described, the concentration distribution of microparticulate in the particulate base member may be easily changed without changing a thickness of the catalytic agent layer. In addition, an amount of additive element (mixture ratio) of Ru and elements such as, Hf, Ta, Mo, W, Ni, and Si, with respect to the main element Pt may be appropriately set to a desired amount or ratio. In a case where an amount of Pt is reduced, amount of Ru and other elements increases. However, depending on the additive element, this causes the power generation efficiency to be improved for a low concentration methanol fuel, which is preferable.

### First Example

In the example, the areas of the first and second sputtering sources taking rectangular shapes and the positions of the respective sputtering sources and the magnets corresponding thereto were regulated in such a manner that platinum and tungsten had a sputtering speed of 4:1. More specifically, the tungsten has a slightly higher sputtering speed than platinum. Therefore, the area was set to be 1:2 and the magnetic flux density in the vicinity of the surface of the second magnet corresponding to the second sputtering source was set to be 80% of the first magnet corresponding to the first sputtering source of the platinum.

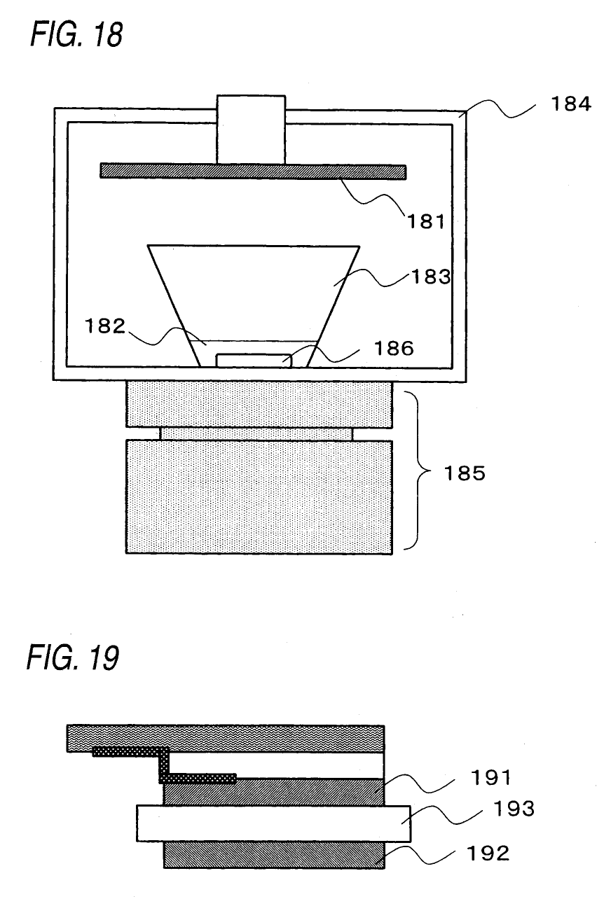

FIG. 18 is a typical sectional view showing a state brought when sputtering is performed over a particulate base material by using a sputtering source 181 formed as described above. A supporting member 183 accommodating a particulate base material 182 containing, as a parent body, carbon having an average particle size of 1 μm or less and a surface area of 50 m²/g or more was put opposite to a lower part of the sputtering source 181 thus formed (a magnet corresponding to the sputtering source is not shown), and the sputtering was performed for 10 hours on the following conditions. In this case, a rotor 186 obtained by coating a magnetic substance with Teflon (registered trademark: produced by DuPont Co., Ltd.) which was previously put in the supporting member 183 was rotated for a certain period of time every certain cycle to stir the particulate base material by using a magnetic stirrer 185 disposed on an outside of a vacuum chamber 184.

Pressure: 1×10⁻² Pa

Period of time for no-stirring: 100 seconds

Period of time for stirring: five seconds

Amount of evaporation: 1×10¹⁵ atoms/cm²·second

Consequently, there was prepared 100 g of platinum-tungsten catalyst carrying carbon powder having a carrying rate of 50% (a weight of a catalyst to that of carbon).

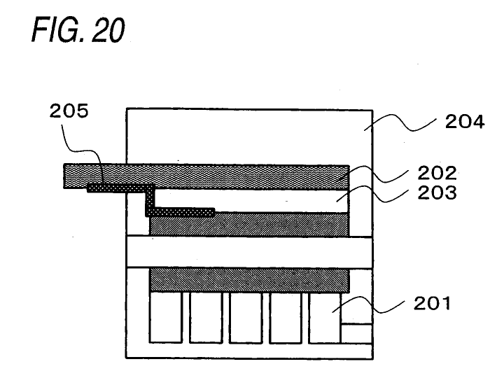

FIG. 19 is a typical view showing a film and electrode complex for a catalytic evaluation according to the example. FIG. 20 is a typical view showing a single cell of a direct methanol fuel cell incorporating the film and electrode complex.

By using the powder thus obtained, a cathode electrode 191 and an anode electrode 192 were produced respectively and were subjected to thermo-compression bonding at 125 degrees Celsius for 10 minutes at a pressure of 30 kg/cm² with a proton conducting solid polymer film 193 formed of Nafion (registered trademark; produced by DuPont Co., Ltd.) which was interposed between the cathode electrode 191 and the anode electrode 192 so that a film and electrode complex (MEA) was produced. By using the film and electrode complex, and a channel plate 201, a fuel penetrating portion 202, a vaporizing portion 203, a separator 204 and a lead wire 205, the single cell of the direct methanol fuel cell was produced. In the single cell, a 1 M methanol solution to be a fuel was supplied in a flow rate of 0.6 ml/min. to the anode electrode 192 and air was supplied in a flow rate of 200 ml/minute to the cathode electrode 191, and a discharge was carried out to maintain a current density of 150 mA/cm² in a state in which the cell was maintained at 65 degrees Celsius and a cell voltage was measured after 30 minutes. Consequently, a voltage of 0.6 V was obtained. The voltage thus obtained had a greater value by 20% or more as compared with the case in which the single cell was produced in an equal amount of a noble metal. In a case in which the single cell is produced through a vacuum process, thus, the sputtered ruthenium is not oxidized. Therefore, it is possible to suppose that a small elution is generated through formic acid in a power generating process and deterioration in a characteristic in use for a long period of time is reduced. The platinum and tungsten sputtering sources were consumed almost uniformly and the alloy could be efficiently carried on a deposited substrate. Moreover, the sputtering source could also be reprocessed easily. The obtained alloy particle had an average particle size of 4 nm.

### Second Example

In the following example, portions different from the first example will be mainly described and identical mechanism to those in the first example will be omitted. In the first example, a magnetic force of a magnet was previously varied corresponding to a composition of a catalyst and a component element of an alloy to change a magnetic flux density in the vicinity of a surface of the sputtering source. In the example, however, a magnetic flux density was regulated by using the mechanism shown in FIG. 2 so as to obtain a proper composition even if a component element of an alloy was changed. Platinum and niobium were selected for the sputtering source to carry an alloy having a ratio of platinum to niobium of 4:1. Since a sputtering speed of the niobium is higher than that of the platinum, an area of the sputtering source was set to be ½, and furthermore, a magnet was separated from a backing plate by 10 mm in such a manner that the magnetic flux density was reduced by 30%. The other conditions were set in the same manner as in the first example and sputtering was performed for 10 hours to perform an evaluation through a single cell. Consequently, a voltage of 0.6 V was obtained. This is a greater value by 20% or more as compared with the case in which the single cell is produced in an equal amount of a noble metal. Platinum and niobium sputtering sources were consumed almost uniformly and the alloy could be efficiently carried on a deposited substance. Moreover, the sputtering source could also be reprocessed easily. The obtained alloy particle had an average particle size of 4 nm.

### Third Example

In the first and second examples, the material was exchanged for a new one immediately before a hole was formed in the erosion area of the sputtering source and the residual material was regenerated. In the example, the structure shown in FIG. 11 was employed to increase utilization efficiency of the material. For a sputtering source, there ware used a first sputtering source containing platinum and a second sputtering source containing vanadium. The other conditions were set in the same manner as in the first example and sputtering was performed for 20 hours. An evaluation was performed through a single cell. Consequently, a voltage of 0.6 V was obtained. This is a greater value by 20% or more as compared with the case in which the single cell is produced in an equal amount of a noble metal. As a result, a power generating efficiency was also enhanced. On the other hand, a rectangular plate-shaped material was also sputtered almost uniformly so that utilization efficiency could be set to be 80% or more. Platinum and vanadium sputtering sources were consumed almost uniformly and the alloy could be efficiently carried on a deposited substance. The utilization efficiencies of the platinum and the vanadium could be increased and a noble metal material could also be reprocessed. The obtained alloy particle had an average particle size of 4 nm.

According to the invention, it is possible to provide a method and apparatus for causing a particulate carrier having a particle size of 1 μm or less to carry a microparticle having a particle size of 10 nm or less, and an application includes a direct methanol fuel cell utilizing the powder for a catalyst.

s

It is to be understood that the present invention is not limited to the specific embodiment described above and that the invention can be embodied with the components modified without departing from the spirit and scope of the invention. The invention can be embodied in various forms according to appropriate combinations of the components disclosed in the embodiment described above. For example, some components may be deleted from all components shown in the embodiment. Further, the components in different embodiments may be used appropriately in combination.

What is claimed is:

1. A sputtering apparatus comprising:
a supporting member that accommodates one of a particulate base material and a sheet-type base material;
a first sputtering source that is disposed to face the supporting member at a first distance, the first sputtering source containing platinum and having a rectangular shape;
a second sputtering source that is disposed to face the supporting member at a second distance and to be adjacent to the first sputtering source, the second sputtering source containing an element different from that contained in the first sputtering source;
a first magnet that is disposed to face the supporting member at an opposite side with respect to the first sputtering source, the first magnet applying a first magnetic field near a surface of the first sputtering source in a first magnetic flux density; and
a second magnet that is disposed to face the supporting member at an opposite side with respect to the second sputtering source, the second magnet applying a second magnetic field near a surface of the second sputtering source in a second magnetic flux density,
wherein at least one of the first magnetic flux density and the second magnetic flux density is configured to be variable.

2. The apparatus according to claim 1, wherein at least one of the first distance and the second distance is configured to be adjustable to vary at least one of the first magnetic flux density and the second magnetic flux density.

3. The apparatus according to claim 1, wherein at least one of a first magnetic force of the first magnet and the second magnetic force of the second magnet is configured to be adjustable to vary at least one of the first magnetic flux density and the second magnetic flux density.

4. The apparatus according to claim 1 further comprising a mechanism that varies at least one of a first position of the first magnet with respect to the first sputtering source and a second position of the second magnet with respect to the second sputtering source.

5. The apparatus according to claim 1, wherein the first sputtering source includes at least two first sputtering source pieces, and
wherein the second sputtering source is disposed between the first sputtering source pieces so as that longitudinal edges of the first sputtering source pieces and the second sputtering source are arranged to be substantially in parallel with one another.

6. The apparatus according to claim 1 further comprising a third sputtering source that is disposed to face the supporting member and to be adjacent to at least one of the first sputtering source and the second sputtering source, the third sputtering source containing an element different from those contained in the first sputtering source and the second sputtering source.

7. The apparatus according to claim 1, wherein the particulate base material and the sheet-type base material contain carbon as a main component.

8. The apparatus according to claim 1 further comprising a high-permeability member that is disposed between the second sputtering source and the second magnet, the high-permeability member having permeability higher than that of the first sputtering source and the second sputtering source.

9. The apparatus according to claim 4, wherein the mechanism is configured to operate to:
move a relational position between the first and second sputtering sources and the first and second magnets in a given direction to scan the first and second sputtering sources with the first and second magnets; and
move the relational position in an opposite direction that is opposite the given direction at a given position.

10. The apparatus according to claim 9, wherein a thickness of the first and second sputtering sources at a position near the given position is formed to be thicker than other areas.

11. The apparatus according to claim 9 further comprising an additional member that is disposed between at least one of the first and second sputtering sources and the first and second magnets at a position near the given position,
wherein the additional member is formed of a material that is selected from a group consisting of: a material forming the first sputtering source; a material forming the second sputtering source; SiO₂; TiO₂; WO₃; and Mn.

12. The apparatus according to claim 9 further comprising a high-permeability member that is disposed between the first and second sputtering sources and the first and second magnets at a position near the given position, the high-permeability member having permeability higher than that of the first sputtering source and the second sputtering source.

13. The apparatus according to claim 9, wherein the mechanism moves the relative position at a position near the given position at a speed higher than that at other areas.

14. The apparatus according to claim 4, wherein the mechanism moves a relational position between the first and second sputtering sources and the first and second magnets unidirectionally at a constant speed.

15. A cell for a direct methanol fuel cell including microparticulate that is produced using the sputtering apparatus according to claim 1.

16. A sputtering apparatus comprising:
a supporting member that accommodates one of a particulate base material and a sheet-type base material;
a first sputtering source that includes at least two sputtering source pieces that are disposed to face the supporting member, each of the sputtering source pieces containing platinum and having a rectangular shape;
a second sputtering source that is disposed to face the supporting member and to be adjacent to the sputtering source pieces, the second sputtering source containing an element different from that contained in the first sputtering source;
a magnet that is disposed to face the supporting member at an opposite side with respect to the first sputtering source and the second sputtering source, the magnet applying a magnetic field near a surface of the first sputtering source and the second sputtering source,
wherein the second sputtering source is disposed between the sputtering source pieces so as that longitudinal edges of the sputtering source pieces and the second sputtering source are arranged to be substantially in parallel with one another,
wherein the magnetic field is configured to be in a longitudinal shape that extends in a direction that is substantially orthogonal to the longitudinal edges of the sputtering source pieces and the second sputtering source, and
wherein the magnetic field is configured to be movable in a direction along the longitudinal edges of the sputtering source pieces and the second sputtering source, by relatively moving the magnet and a set of the first sputtering source and the second sputtering source.
